(19) United States
(12) Patent Application Publication
(10) Pub. No.: US 2007/0209830 A1
(43) Pub. Date: Sep. 13, 2007

(54) Semiconductor chip package having a slot type metal film carrying a wire-bonding chip

(75) Inventor: Ping-Hua Chu, Kaohsiung (TW)

Correspondence Address: TROXELL LAW OFFICE PLLC, SUITE 1404, 5205 LEESBURG PIKE, FALLS CHURCH, VA, 22041, US

(73) Assignee: Walton Advanced Engineering, Inc.

(21) Appl. No.: 11/373,315

(22) Filed: Mar. 13, 2006

(51) Int. Cl. H05K 1/11; H01R 12/04

(52) U.S. Cl. 174/261

(57) ABSTRACT

A chip package with COB configuration is disclosed. A thin film substrate as a carrier of a wire-bonded chip has a slot, wherein the electrical connection between the chip and the thin film substrate are a plurality of bonding wires through the slot. The thin film substrate includes a patterned metal core with resin and at least a solder resist layer on the patterned metal core, wherein the patterned metal core has a plurality of finger pads and a plurality of ball pads. The finger pads are disposed around the slot. When the active surface of the chip is attached to the thin film substrate, the patterned metal core provides a good thermal dissipation for the chip. Moreover, the chip package using thin film substrates can reduce the cost of the substrate and the overall thickness of the package and enhance the cushion effect against thermal stress.

### FIELD OF THE INVENTION

The present invention relates to a semiconductor chip package, and more particularly to a semiconductor chip package with COB (Chip-On-Board) configuration.

### BACKGROUND OF THE INVENTION

COB (Chip-On-Board) packaging is a very common semiconductor packaging technique. There are three major processes in COB packaging, (1) chip-attaching: a chip is directly attached to a substrate with a slot, (2) electrical connection: a plurality of bonding wires are bonded through the slot of the substrate for electrically connecting the chip and the substrate, and (3) encapsulation: the chip is encapsulated. Furthermore, a plurality of solder balls are then placed on the substrate to form a BGA type COB package for high performance IC chips. Popularly, COB packages have been implemented for high frequent memory chips to replace the conventional memory chip packages in TSOP to increase operation speeds.

As shown in FIG. 1, a conventional COB package 100 comprises a rigid substrate 110, a chip 120, a plurality of bonding wires 130, and an encapsulant 140. Therein the rigid substrate 110 is a PWB and has an upper surface 111, a bottom surface 112, and a slot 113 penetrating through the upper surface 111 and the bottom surface 112 for the bonding wires 130 to go through. The PWB rigid substrate 110 has at least a core layer 114 made of glass fibers with pre-preg, and further includes finger pads 115 and ball pads 116 formed from a copper foil and a solder mask 117. However, the rigid substrate 110 is normally thick with high thermal resistance and poor cushion effect against thermal stress. The chip 120 has an active surface 121 and a corresponding back surface 122 where a plurality of bonding pads 123 are formed on the active surface 121. The active surface 121 of the chip 120 is attached to the upper surface 111 of the rigid substrate 110 utilizing a die attach material 124. The bonding pads 123 are located and aligned inside the slot 113 so that the bonding pads 123 and the finger pads 115 are electrically connected by the bonding wires 130 through the slot 113. Moreover, an encapsulant 140 is formed on the upper surface 111 and in the slot 113 of the rigid substrate 110 to encapsulate the chip 120 and the bonding wires 130. A plurality of solder balls 150 are placed on the ball pads 116 on the bottom surface 112. Therefore, the thickness, the thermal resistance, and the cushion effect of the rigid substrate 110 of the conventional COB package 100 can further be improved.

In another conventional COB package, PI (polyimide) wiring film is used to replace the rigid substrates 110 for a thinner profile. Since the thermal conductivity of PI is not good, therefore, the overall thermal dissipation of the COB package is not greatly improved. Moreover, the PI wiring film as substrate is expensive.

Another COB package is revealed from U.S. Pat. No. 6,385,049, entitled “multi-board BGA package”.

### SUMMARY OF THE INVENTION

The main purpose of the present invention is to provide a chip package utilizing a thin film substrate with a slot or a plurality of coplanar thin film substrates where the active surface of the chip is attached to the thin film substrate(s). The thin film substrate includes a patterned metal core with resin and at least a solder resist layer on the patterned metal core where the patterned metal core has a plurality of finger pads and a plurality of ball pads. The patterned metal core can provide a good thermal dissipation and electrical transmission for the chip. Not only can the overall thickness of the package be reduced, but also can the cushion effect against thermal stress be enhanced. Moreover, the cost of the substrate also can further be reduced.

The second purpose of the present invention is to provide a chip package where the patterned metal core of the thin film substrate further has a plurality of connecting bars as plating lines which connect the ball pads toward sides of the thin film substrate or connect the finger pads toward the slot/wire-bonding spacing for electrical plating and enhancing the firmness of the finger pads and the ball pads to avoid electric shorts during packaging processes.

The third purpose of the present invention is to provide a chip package where the ball pads of the patterned metal core are irregularly shaped in non-circular patterns to enhance thermal dissipation. Moreover, the openings of the solder resist layer are circular for placing solder balls to become a BGA package.

According to the present invention, a chip package mainly comprises a thin film substrate, a chip, a plurality of bonding wires, and an encapsulant, wherein the thin film substrate has a slot for wire-bonding. The thin film substrate includes a patterned metal core with resin and at least a solder resist layer on the patterned metal core. The patterned metal core includes a plurality of finger pads and a plurality of ball pads where the finger pads are located around the slot and electrically connected to the ball pads by a plurality of traces of the patterned metal core. A plurality of electrodes, for example bonding pads, are formed on the active surface of the chip. When the active surface is attached to the thin film substrate, the electrodes are located within the slot. Bonding wires are used to electrically connect the electrodes and the finger pads through the slot. Furthermore, an encapsulant is formed in the slot and on the thin film substrate to encapsulate the bonding wires and at least a portion of the chip.

### DESCRIPTION OF THE DRAWINGS

FIG. 1 is a cross-sectional view of a conventional COB chip package wire-bonding through a slot of a PWB substrate.

FIG. 2 is a cross-sectional view of the chip package according to the first embodiment of the present invention.

FIG. 3A to 3I are the cross-sectional views of the chip package during packaging processes according to the first embodiment of the present invention.

FIG. 4 is the partial bottom view of the chip package before the electrical plating on the patterned metal core according to the first embodiment of the present invention.

FIG. 5 is the bottom view of a plurality of thin film substrates of another chip package according to the second embodiment of the present invention.

FIG. 6 is a cross-sectional view of the chip package according to the second embodiment of the present invention.

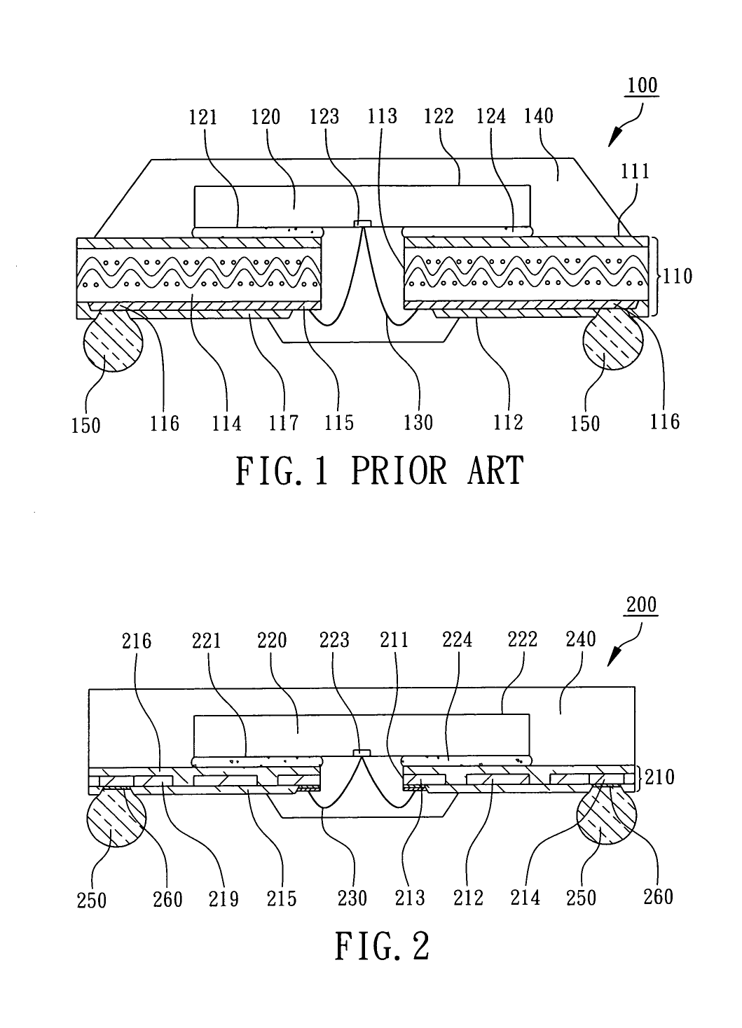

### DETAIL DESCRIPTION OF THE INVENTION

Please refer to the attached drawings, the present invention will be described by means of embodiment(s) below.

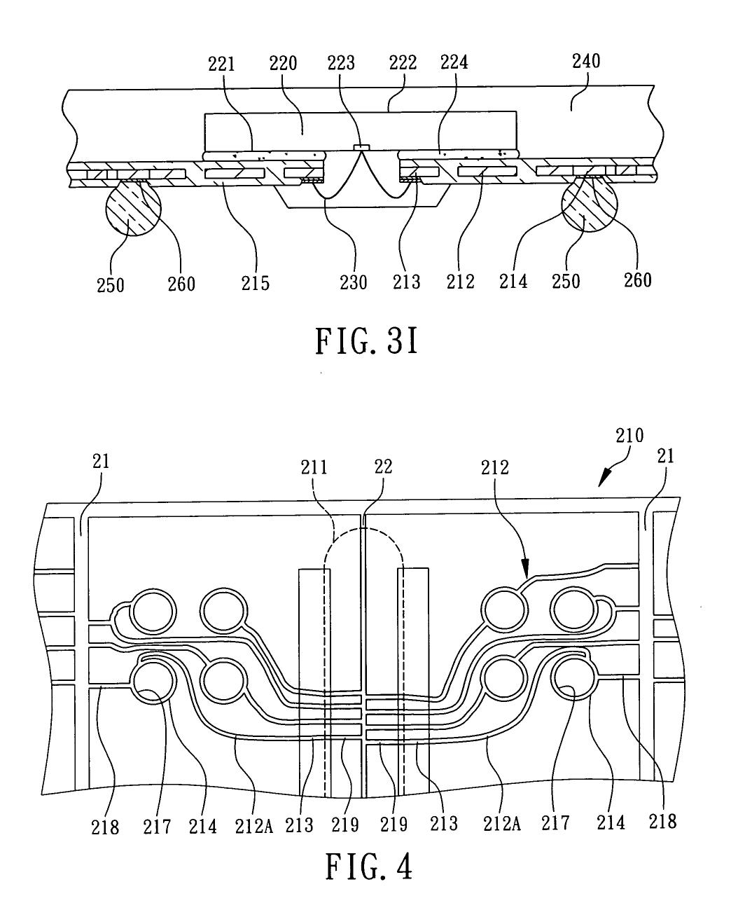

A chip package is illustrated in the first embodiment according to present invention. As shown in FIG. 2, a chip package 200 comprises a thin film substrate 210, a chip 220, a plurality of bonding wires 230, and an encapsulant 240. The thin film substrate 210 has a slot 211 penetrating from the upper surface to the bottom surface of the substrate 210. The thin film substrate 210 includes a patterned metal core 212 with resin and at least a solder resist layer on the patterned metal core 212. The patterned metal core 212 has a plurality of finger pads 213 and a plurality of ball pads 214. Therein the finger pads 213 are located around the slot 211. The ball pads 214 are arranged in an array or in linear layout with dual-row or multi-row layout. The finger pads 213 are electrically connected to the corresponding ball pads 214 by a plurality of metal traces 212A of the patterned metal core 212 (as shown in FIG. 4). In this embodiment, the thickness of the patterned metal core 212 ranges from 60 to 100 um (micrometer), which is larger than the thickness (about 35 um) of wiring layer on PI core of the conventional flexible printed circuit board to provide better mechanical strength, electrical transmission, and thermal dissipation for the thin film substrate 210. Therefore, the patterned metal core 212 can replace the PI dielectric core and the copper trace layers of the conventional flexible printed circuit boards with better thermal dissipation, thinner package, and lower cost. Furthermore, there are two layers of the solder resist layer, the first solder resist layer 215 and the second solder resist layer 216, on the lower and upper surfaces of the thin film substrate 210, so that the patterned metal core 212 are sandwiched between the first solder resist layer 215 and the second solder resist layer 216. As shown in FIG. 4, the first solder resist layer 215 has a plurality of openings 217 corresponding to the ball pads 214 and a slot exposing the finger pads 213. Preferably, the material of the first solder resist layer 215 can be chosen from liquid photo-imagable solder mask (LPI), or photo-imagable cover layer (PIC). The material of second solder resist layer 216 can be chosen from non-photo sensitive dielectric materials. The chip 220 has an active surface 221 and a corresponding back surface 222. A plurality of electrodes 223 are formed on the active surface 221 such as bonding pads or bumps, formed at the center or at the peripheries of the active surface 221. The electrodes 223 can be arranged in a single row or in multiple rows. The active surface 221 is attached to the thin film substrate 210 by a die attach layer 224 where the electrodes 223 are located within the slot 211. The electrodes 223 are electrically connected to the finger pads 213 by a plurality of bonding wires 230 passing through the slot 211. Moreover, an encapsulant 240 is formed in the slot 211 and on the thin film substrate 210 to encapsulate the bonding wires 230 and the chip 220 respectively. The back surface 222 of the chip 220 may be covered or exposed from the encapsulant 240. The encapsulant 240 is a molding compound or an underfill material or proper potting materials to at least partially encapsulate the side walls of the chip 220 or completely encapsulate the chip 220. In this embodiment, the chip package 200 further comprises a plurality of solder balls 250 placed on the ball pads 214 to allow the COB package have the characteristics of BGA packages.

Since the patterned metal core 212 is adjacent the active surface 221 of the attached chip 220, therefore, good thermal dissipation is provided. The heat generated from the active surface 221 of the chip 220 will be thermally dissipated through the patterned metal core 212 so that heat dissipation of the COB thin film package 200 can be enhanced. Moreover, the cost of the substrate and the overall package thickness can further be reduced and the cushion effect of thermal stress can further be enhanced. Preferably, as shown in FIG. 4, the patterned metal core 212 further includes a plurality of first connecting bars 218 to connect the ball pads 214 and extend to the peripheries of the thin film substrate 210 for fastening the ball pads 214 and electroplating. Particularly, the patterned metal core 212 further includes a plurality of second connecting bars 219 to connect the finger pads 213 to the sides of the slot 211. As shown in FIG. 2, a plated layer 260 such as nickel-gold can be formed on the finger pads 213 and the ball pads 214. In the present embodiment, the patterned metal core 212 has both the first connecting bars 218 and the second connecting bars 219 to enhance the mechanical strength of the finger pads 213 and the ball pads 214. Before resin filling, the first connecting bars 218 connect the ball pads 214 to the plating lines 21 on the scribe lines between two units of the thin film substrates 210. The second connecting bars 219 connect the finger pads 213 to the plating lines 22 cross two ends of the slot 211 before routing. Moreover, the finger pads 213, the ball pads 214, and the traces 212A of the patterned metal core 212 can be firmly fixed when disposing the first solder resist layer 215 and the second solder resist layer 216 to avoid electrical shorts between fine pitch finger pads 213.

Preferably, the ball pads 214 are irregularly extended as large as possible in non-circular patterns to increase heat dissipation area. However the openings 217 are circular for placing solder balls 250. Therefore, the openings 217 of the first solder resist layer 215 are smaller than the ball pads 214 to cover the peripheries of the ball pads 214. When the first solder resist layer 215 is a solder mask, the ball pads 214 can be solder mask defined pads, SMD pads.

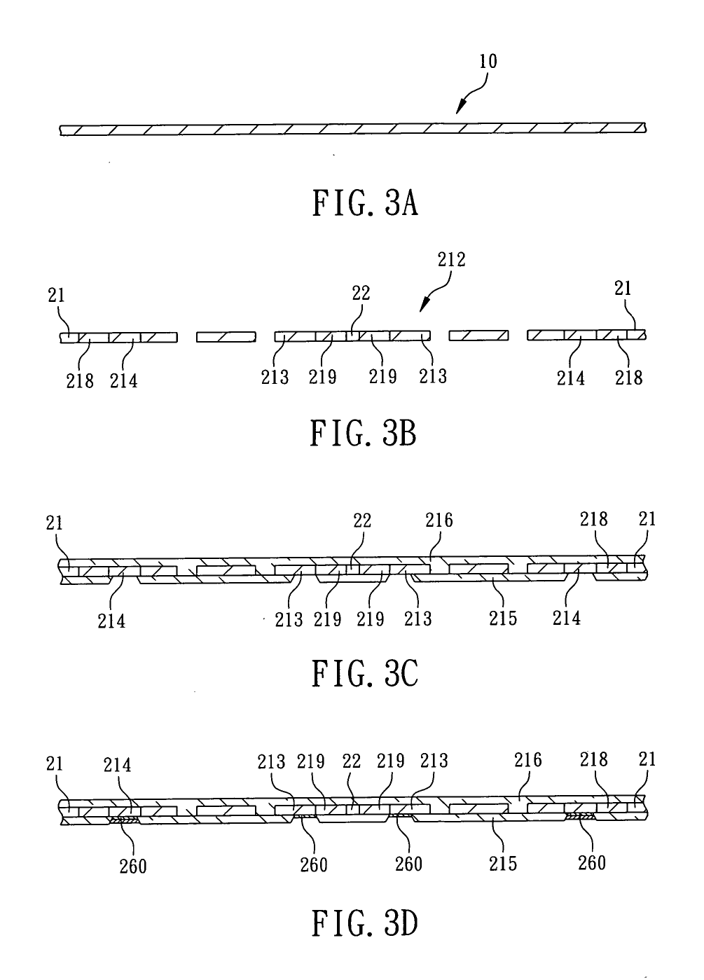

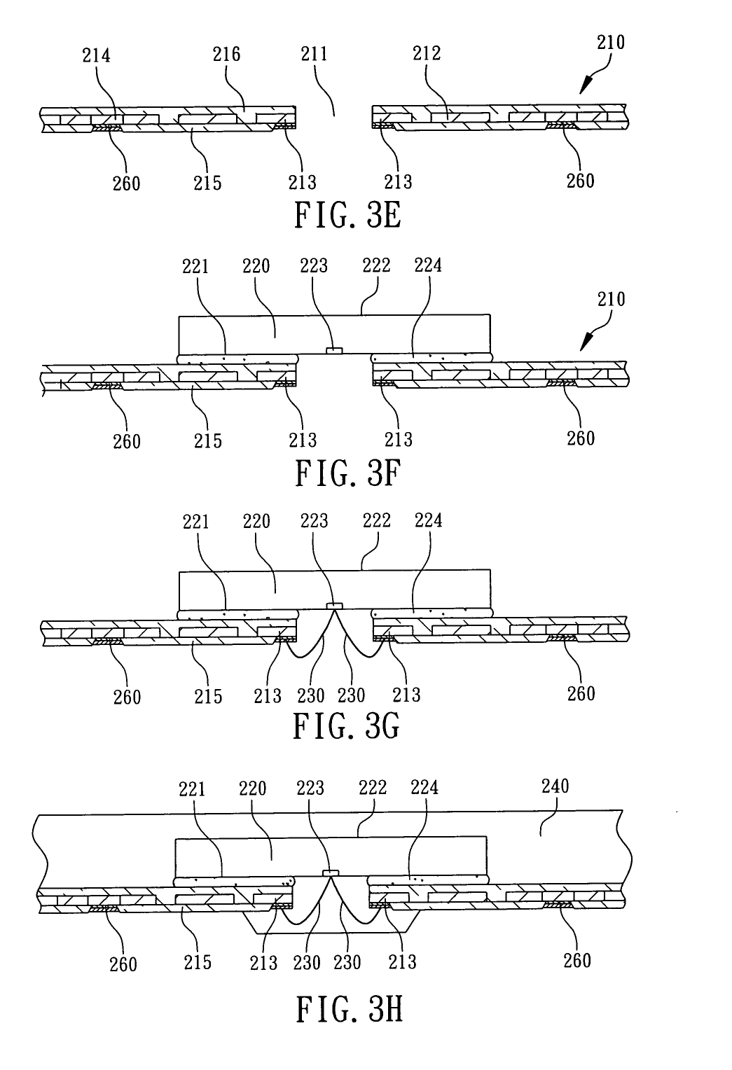

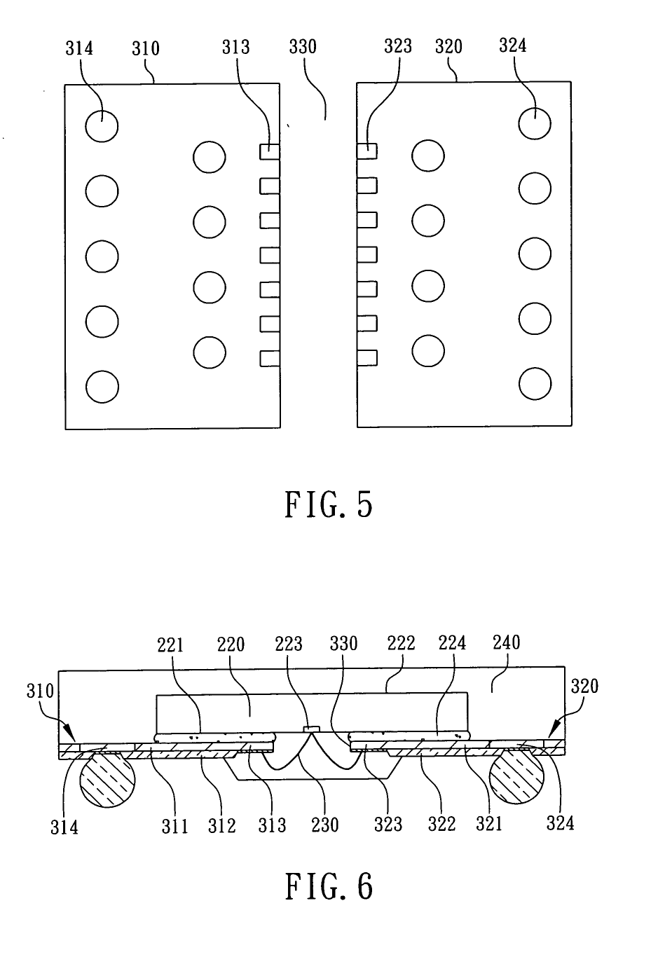

The assembling processes of the chip package 200 mentioned above are described from FIG. 3A to FIG. 3I. Initially, as shown in FIG. 3A, a copper foil 10 with a thickness between 60 and 100 um is provided. Then, the copper foil 10 is patterned utilizing photolithography including exposure and development, and then etching processes. As shown in FIG. 3B, the copper foil 10 becomes the patterned metal core 212 having finger pads 213 and ball pads 214 after patterning. In the present embodiment, as shown in FIG. 4, the ball pads 214 are connected to the plating lines 21 on the scribe lines by connecting bars 218, the finger pads 213 to the plating lines 22 in the slot 211 by the second connecting bars 219 before the slot 211 is routed. As shown in FIG. 3C, the first solder resist layer 215 and the second solder resist layer 216 are printed on the bottom surface and the upper surface of the patterned metal core 212. Then a plurality of openings 217 and a slot are formed in the first solder resist layer 215 to expose the ball pads 214 and the finger pads 213. Then, as shown in FIG. 3D, a plated layer 260 are disposed on the exposed area of the ball pads 214 and the finger pads 213 by a plating process. Then a routing process is followed, as shown in FIG. 3E, to form the slot 211. The thin film substrate 210 is made. In the present embodiment, the second connecting bars 219 are removed while routing the slot 211, however, the first connecting bars 218 are remained in the thin film substrate 210. Then, as shown in FIG. 3F, the active surface 221 of the chip 220 is attached to the upper surface of the thin film substrate 210 with the electrodes 223 of the chip 220 exposed from the slot 211. Next, as shown in FIG. 3G, the electrodes 223 are electrically connected to the finger pads 213 by a plurality of bonding wires 230 through the slot 211. As shown in FIG. 3H, an encapsulant 240 is formed on the upper surface of the thin film substrate 220 and in the slot 211 to encapsulate the chip 220 and the bonding wires 230 but the ball pads 214 are exposed for external electrical connection. Then, as shown in FIG. 3I, a plurality of solder balls 250 are placed on the ball pads 214 by solder reflow or solder joining technique. Finally, a substrate singulation is followed to form the individual chip packages 200 as shown in FIG. 2. According to the second embodiment of the present invention, the single thin film substrate 210 having the slot 213 can be replaced by a plurality of coplanar thin film substrates. As shown in FIG. 5, another chip package mainly comprises the chip 220, bonding wires 230, an encapsulant 240, and a first thin film substrate 310 and a second thin film substrate 320. The active surface 221 of the chip 220 are attached to the first thin film substrate 310 and the second thin film substrate 320. As shown in FIG. 5 and FIG. 6, the first thin film substrate 310 and the second thin film substrate 320 are formed in the same plane where a wire-bonding spacing 330 is formed between the first thin film substrate 310 and the second thin film substrate 320 for the passage of bonding wires. The first thin film substrate 310 includes a patterned metal core 311 with resin and at least a solder resist layer 312 on the patterned metal core 311 where the patterned metal core 311 includes a plurality of finger pads 313 and a plurality of ball pads 314 in a same layer. The finger pads 313 are located adjacent the wire-bonding spacing 330, the ball pads 314 are disposed in an array. Similarly, the second thin film substrate 320 includes a patterned metal core 321 and at least a solder resist layer 322. The patterned metal core 321 has a plurality of finger pads 323 and a plurality of ball pads 324. The separation of the first thin film substrate 310 and the second thin film substrate 320 can enhance cushion effect against thermal stress resistance. When the chip package is surface-mounted on an external printed circuit board, the thermal stresses generated by the thermal cycles will be spread and absorbed by the first thin film substrate 310 and the second thin film substrate 320 and will not impact on the chip to avoid delamination between the chip and the thin film substrates 310 and 320. Therefore, the overall thickness can be reduced and heat dissipation can be increased with lower cost substrates.

The above description of embodiments of this invention is intended to be illustrative and not limiting. Other embodiments of this invention will be obvious to those skilled in the art in view of the above disclosure.

What is claimed is:

1. A chip package comprising:
a thin film substrate having a slot and including a patterned metal core with resin and a first solder resist layer on the patterned metal core, wherein the patterned metal core has a plurality of finger pads and a plurality of ball pads, where the finger pads are located around the slot and electrically connected to the ball pads by a plurality of traces of the patterned metal core;
a chip having a plurality of electrodes on an active surface, wherein the active surface is attached to the thin film substrate in a manner that the electrodes are located within the slot;
a plurality of bonding wires electrically connecting the electrodes to the finger pads through the slot; and
an encapsulant formed in the slot and on the thin film substrate to encapsulate the bonding wires and at least a portion of the chip.

2. The chip package of claim 1, wherein the thickness of the patterned metal core is between 60 and 100 um.

3. The chip package of claim 1, wherein the patterned metal core further includes a plurality of connecting bars connecting the ball pads and extending to peripheries of the thin film substrate.

4. The chip package of claim 1, wherein the patterned metal core further includes a plurality of connecting bars connecting the finger pads and extending to sides of the slot.

5. The chip package of claim 1, wherein the first solder resist layer has a plurality of openings smaller than the ball pads to cover the peripheries of the ball pads.

6. The chip package of claim 5, wherein the ball pads are irregularly shaped in non-circular patterns and the openings are circular.

7. The chip package of claim 5, wherein the first solder resist layer is a solder mask.

8. The chip package of claim 1, further comprising a plurality of solder balls placed on the ball pads.

9. The chip package of claim 1, wherein the thin film substrate comprises a second solder resist layer opposing to the first solder resist layer to sandwich the patterned metal core therebetween.

10. A chip package comprising:
a plurality of thin film substrates which are coplanar, wherein a wire-bonding spacing is formed between the thin film substrates, each of the thin film substrates includes a patterned metal core with resin and a first solder resist layer on the patterned metal core, wherein the patterned metal core has a plurality of finger pads and a plurality of ball pads, where the finger pads are located adjacent the wire-bonding spacing;
a chip having a plurality of electrodes on an active surface, wherein the active surface is attached to the thin film substrates in a manner that the electrodes are located within in the wire bonding spacing;
a plurality of bonding wires electrically connecting the electrodes to the finger pads through the wire bonding spacing; and
an encapsulant forming in the wire bonding spacing and on the thin film substrates to encapsulate the bonding wires and at least a portion of the chip.

11. The chip package of claim 10, wherein the thickness of the patterned metal cores is between 60 and 100 um.

12. The chip package of claim 10, wherein the patterned metal core further includes a plurality of connecting bars connecting the ball pads and extending to peripheries of the thin film substrates.

13. The chip package of claim 10, wherein the patterned metal core further includes a plurality of connecting bars connecting the finger pads and extending to sides of the wire-bonding spacing.

14. The chip package of claim 10, wherein the first solder resist layer has a plurality of openings smaller than the ball pads to cover the peripheries of the ball pads.

15. The chip package of claim 14, wherein the ball pads are irregularly shaped in non-circular patterns and the openings are circular.

16. The chip package of claim 14, wherein the first solder resist layers are solder masks.

17. The chip package of claim 10, further comprising a plurality of solder balls placed on the ball pads.

18. The chip package of claim 10, wherein each of the thin film substrates further includes a second solder resist layer opposing to the first solder resist layer to sandwich the patterned metal core therebetween.
